(19) United States
(12) Patent Application Publication
(10) Pub. No.: US 2010/0157599 A1
(43) Pub. Date: Jun. 24, 2010

(54) Method and Apparatus for Forming a Thermal Interface for an Electronic Assembly

(75) Inventors: James Anthony Carter, East Greenwich, RI (US); Peter Auld Mackay, Warwick, RI (US)

Correspondence Address: MCCARTER & ENGLISH, LLP NEWARK, FOUR GATEWAY CENTER, 100 MULBERRY STREET, NEWARK, NJ, 07102, US

(73) Assignee: Hayward Industries, Inc., Elizabeth, NJ (US)

(21) Appl. No.: 12/343,729

(22) Filed: Dec. 24, 2008

(51) Int. Cl. B60Q 1/26; B32B 37/10; H05K 7/20

(52) U.S. Cl. 362/249.02; 156/60; 156/358; 361/713

(57) ABSTRACT

A method and apparatus are provided for forming a thermal interface for an electronic product. A thermally conductive polymer having an adhesive layer formed thereon is provided, a surface of an electronic assembly is pressed against the adhesive layer, and the adhesive layer is allowed to cure so that the thermally conductive polymer and the electronic assembly are in thermal communication with each other. The electronic assembly could be pressed against the thermally conductive polymer using a press and die assembly having a pad for supporting the polymer and a controller for controlling operation of the press. The thermally conductive polymer is bonded to the electronic assembly so that no air pockets or voids are formed therebetween.

### BACKGROUND OF THE INVENTION

1. Field of the Invention

The present invention relates to the manufacture of electronics. More specifically, the present invention relates to a method and apparatus for forming a thermal interface for an electronic assembly.

2. Related Art

In the electronics field, it is often necessary to attach an electronic component or assembly (e.g., a transistor, printed circuit board, etc.) to a heat sink so that heat generated by the component is drawn away by the heat sink, thereby preventing damage to the component or assembly. Quite often, heat sinks are formed using metals. However, in certain applications, the use of a metal heat sink may not be practical. For example, it may be desired to provide a device which includes a plastic housing and an electronic assembly mounted in the housing, wherein no external conductive (e.g., metal) components are utilized, so as to prevent a shock if the housing is touched by an individual. As such, an external metal heat sink cannot be used to draw heat away from the electronic assembly to the ambient air surrounding the device. One example of such a device is an underwater, light-emitting diode (LED) pool light, wherein it is desirable to form the housing of the pool light using plastic (polymer) components, yet necessary to draw heat generated by the LEDs of the light away therefrom.

Thermally-conductive and electrically insulative polymer materials are known. These materials allow for the transfer of heat from an object, while preventing the conduction of electricity therethrough. While such materials can be used as a heat sink for electronic assemblies, it is difficult to form a proper interface between the thermally conductive polymer and the electronic assembly, such that no air pockets or voids are present between the polymer and the electronic assembly. If such pockets or voids are present, they detract from the ability of the polymer to transfer heat from the electronic assembly.

### SUMMARY OF THE INVENTION

The present invention relates to a method and apparatus for forming a thermal interface for an electronic assembly. A thermally conductive polymer having an adhesive layer formed thereon is provided. A surface of an electronic assembly is pressed against the adhesive layer, and the adhesive layer is allowed to cure so that the thermally conductive polymer and the electronic assembly are in thermal communication with each other. Importantly, no air gaps or voids are formed between the polymer and the electronic assembly, thus resulting in a thermal interface with good heat transfer characteristics. The electronic assembly could be pressed against the thermally conductive polymer using a press and die assembly having a pad for supporting the polymer and a controller for controlling operation of the press. The electronic assembly could be supported by a plurality of spring-biased support pins which support by the electronic assembly in facing relationship above the polymer, and which are compressed by the die when the press is operated. After pressing the electronic assembly against the polymer and allowing the adhesive layer to cure, the spring-biased support pins urge the completed device away from the pad. In another embodiment of the present invention, the electronic assembly is supported by a plurality of upright support pins, and the press and die assembly press the thermally conductive polymer against the electronic assembly so as to facility curing of same to the electronic assembly.

### BRIEF DESCRIPTION OF THE DRAWINGS

The foregoing features of the invention will be apparent from the following Detailed Description of the Invention, taken in connection with the accompanying drawings, in which:

FIGS. 1A-1B are cross-sectional views showing the method of the present invention for forming a thermal interface for electronic components;

FIG. 2 is a schematic diagram showing an apparatus according to the present invention for forming the thermal interface shown in FIGS. 1A-1B;

FIG. 3 is a front view showing the apparatus of FIG. 2 in greater detail;

FIG. 4 is a top view showing the apparatus of FIGS. 2-3 in greater detail;

FIG. 5 is a side view showing operation of the apparatus of the present invention in greater detail;

FIG. 6 is a perspective view of another embodiment of the apparatus of the present invention;

FIG. 7 is a diagrammatic view showing positioning of support pins of the apparatus shown in FIG. 6, relative to an electronic assembly;

FIG. 8 is an electrical schematic diagram showing the controller 28 of FIG. 2 in greater detail; and

FIGS. 9A-9B are diagrams showing event handling processes programmed into and executed by the programmable logic controller 200 of FIG. 8.

### DETAILED DESCRIPTION OF THE INVENTION

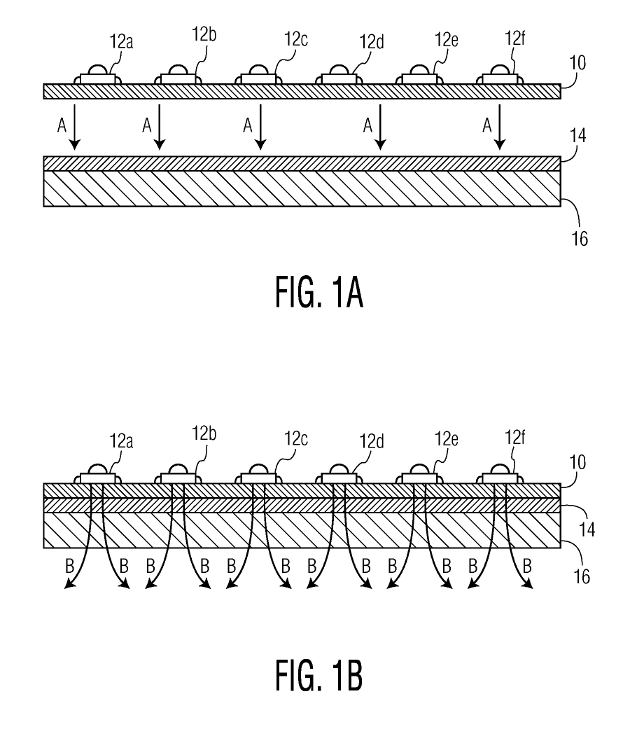

The present invention relates to a method and apparatus for forming a thermal interface for an electronic assembly, as described in detail below with reference to FIGS. 1A-5.

FIGS. 1A-1B are cross-sectional views showing the method of the present invention for forming a thermal interface for electronic components. An electronic assembly 10, such as a printed circuit board having a plurality of light-emitting diodes (LEDs) 12a-12f mounted thereon, is provided. It is noted that other types of electronic devices could be provided, such as any device which require a heat sink to draw heat away therefrom to operate properly. Also provided is a thermally-conductive polymer layer 16 having an adhesive layer 14 formed thereon. The adhesive layer 14 could be formed on the polymer layer 16 using a suitable application process (e.g., coating, chemical deposition, etc.) Also, the polymer layer 16 could be purchased with the adhesive layer 14 pre-formed thereon. The polymer layer 16 could be formed from a layer of material manufactured by Cool Polymers, Inc. under the trade name COOLPOLY, BOND-PLY 100 thermally-conductive, fiberglass-reinforced, pressure sensitive adhesive tape manufactured by the Bergquist company, or thermally-conductive, filled polymer composites, such as those disclosed in U.S. Pat. No. 6,090,484 to Bergerson, the entire disclosure of which is expressly incorporated in its entirety. Such materials are electrically insulative, and thermally conductive, and could be provided pre-cut on a roll. Also, the polymer layer 16 could comprise a dielectric film or a layer of fiberglass. Any other material which is electrically insulative and thermally conductive (e.g., plastic) could be utilized for the polymer layer 16 without departing from the spirit or scope of the present invention.

The electronic assembly 10 is pressed onto the adhesive layer 14, as indicated by arrows A, such that the adhesive layer 14 uniformly contacts the bottom surface of the electronic assembly 10 and no air gaps or voids are formed between the electronic assembly 10 and the adhesive layer 14. It has been found that a pressure of 90 psi maintained against the electronic assembly 10, the adhesive layer 14, and the polymer layer 16 for a duration of 20 seconds is sufficient to ensure that the adhesive layer 14 adequately bonds (cures) with the electronic assembly 10. Of course, other pressures and time durations are possible, and depend on the physical characteristics of the polymer layer 16 and the adhesive layer 14.

As shown in FIG. 1B, when the adhesive layer 14 has bonded with the polymer layer 16 and the electronic assembly 10, heat generated by the LEDs 12a-12f is drawn away therefrom, through the electronic assembly 10, the adhesive layer 14, and the polymer layer 16 (as indicated by arrows B), to the ambient air surrounding the polymer layer 16. As such, the polymer layer 16 functions as a heat sink for drawing heat away from the LEDs 12a-12f The polymer layer 16 could also form part of an external housing for the electronic assembly 10, so as to provide an all-polymer (plastic) housing that is thermally conductive and electrically insulative. Advantageously, this allows for lightweight housings which provide protection against electric shock from and damage to electronic components positioned within such housings. One example of such an application is an all-polymer (plastic) housing for an underwater light, wherein the LEDs 12a-12f provide underwater illumination for a pool or spa. In such circumstances, the polymer layer 16 forms part of an all-polymer housing for the light (in addition to a polymer or glass lens for focusing light generated by the LEDs 12a-12f and protecting same from exposure to water) that is lightweight, protects against shock hazards, and serves to draw heat away from the light. Such a light could be installed in dry or wet niches in a pool or spa.

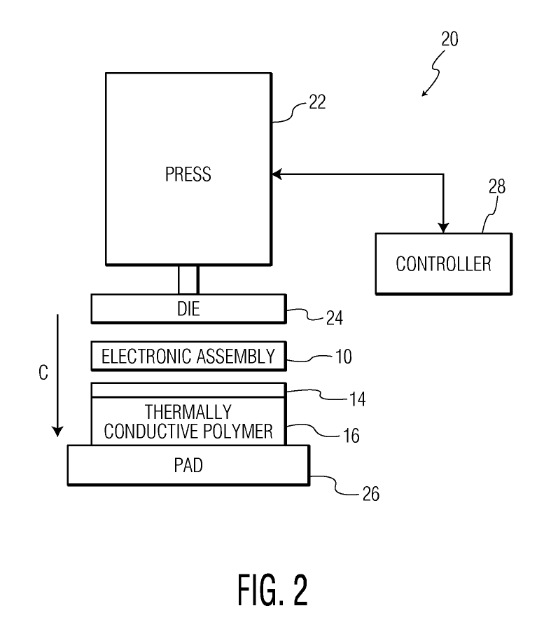

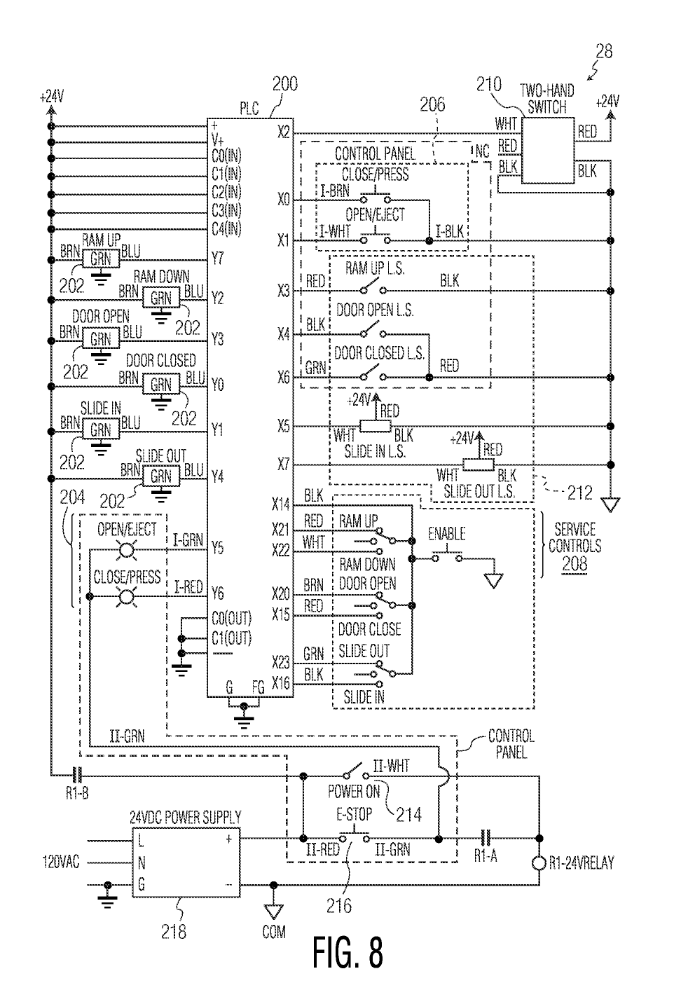

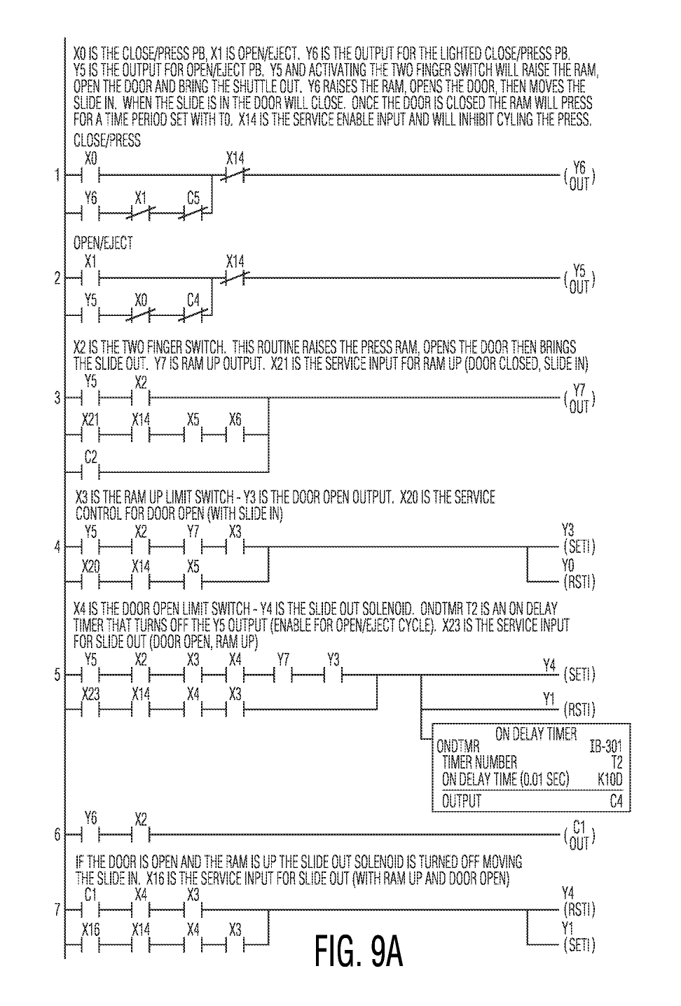

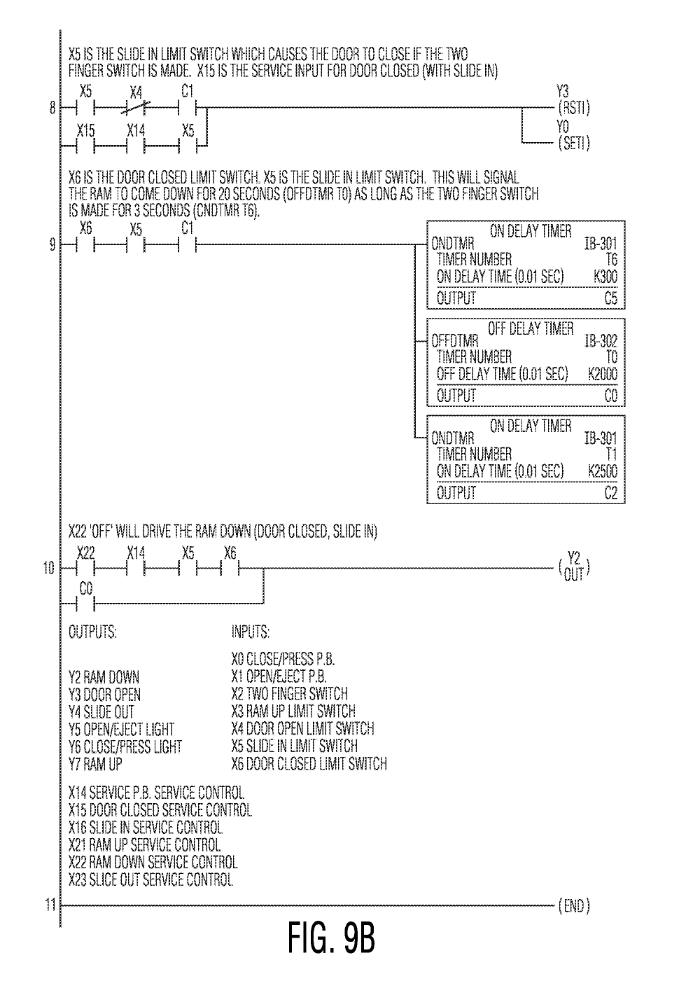

FIG. 2 is a schematic diagram showing an apparatus 20 according to the present invention for forming the thermal interface discussed above in connection with FIGS. 1A-1B. The apparatus 20 includes a press 22 (which could be hydraulically, pneumatically, or electrically driven), a die 24 driven by the press 22, a pad 26, and a controller 28 for controlling operation of the press 22. The electronic assembly 10, the thermally conductive polymer layer 16, and the adhesive layer 14 are positioned between the die 24 and the pad 26, such that the pad 26 supports these components. The press 22 is then operated by the controller 28 to urge the die 24 downward (as shown by arrow C), to contact the electronic assembly 10 and press same against the adhesive layer 14. The die 24 could be shaped so as to apply force to selected portions of the electronic assembly 10 (e.g., to apply force only to selected areas of a printed circuit board), while preventing damage to electronic components mounted to electronic assembly (e.g., resistors, capacitors, diodes, transistors, LEDs, integrated circuits, etc.). The die 24 is pressed against the electronic assembly 10 until the adhesive layer 14 bonds with the electronic assembly 10 and the thermally conductive polymer 16, whereupon the die 24 is lifted from the assembly 10 by the press 22. At this point, the assembly 10 is mounted to the polymer layer 16, and a thermal interface is formed between the assembly 10 and the polymer layer 16. Construction of the controller 28 is described below in connection with FIGS. 8 and 9A-9B.

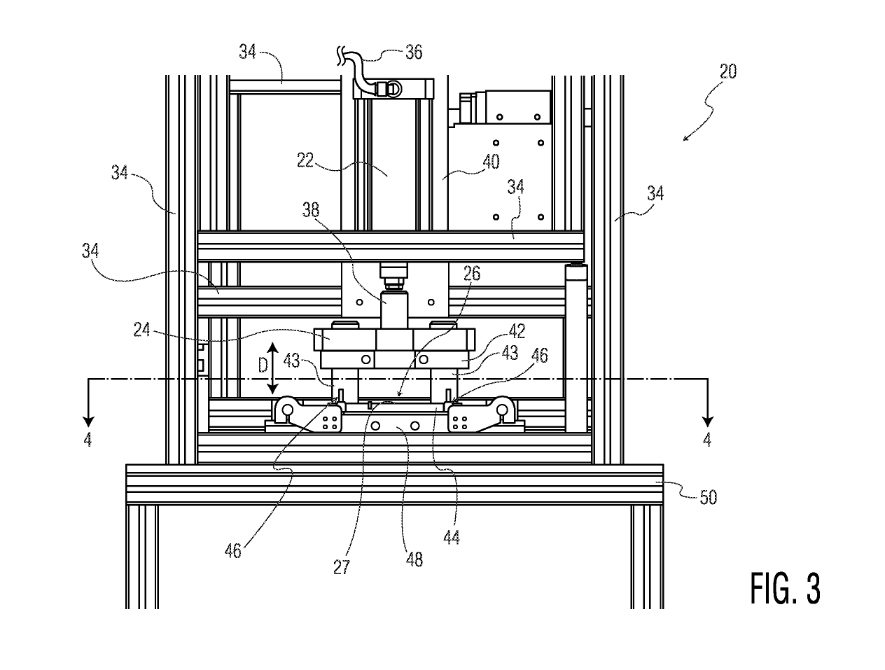

FIG. 3 is a front view showing the apparatus 20 of FIG. 1 in greater detail. The apparatus 20 includes a frame 34 and a mounting plate 40, to which the press 22 is mounted. If the press 22 is pneumatically driven, a tube 36 provides compressed air (e.g., from a compressor) to the press 22. The press 22 is attached to the die 24 by way of shaft 38, such that when the press 22 is actuated, the shaft 38 moves downward, urging the press 24 toward the pad 26 (as indicated by arrow D). The die 24 includes a precision grounding pad 42 for contacting an electronic assembly (e.g., a printed circuit board), and for grounding unwanted electrical charges to prevent same from damaging the electronic assembly when the apparatus 20 is operated. The die 24 and ground pad 42 slide vertically along shafts 43 when actuated by the press 22. The pad 26 includes a low-durometer application surface 44 for receiving a thermally-conductive polymer material and an associated adhesive. A central pin 27 is provided, and is inserted through a hole formed in the thermally-conductive polymer material, so as to facilitate proper alignment of the polymer material on the application surface 44. The pad 26 and application surface 44 are attached to a shuttle assembly 48, discussed below, which allows for horizontal motion of the pad 26 and the application surface 44. Spring-biased support pins 46, also discussed below, support an electronic assembly above the thermally-conductive polymer material prior to operation of the press 22. The apparatus 20 could be supported by a table 50, if desired.

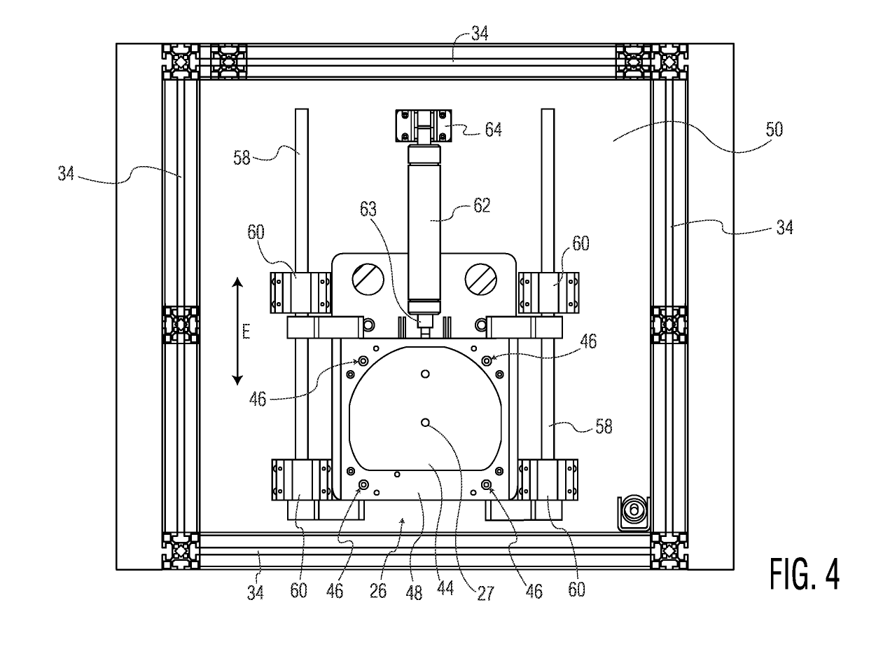

FIG. 4 is a top view, taken along the line 4-4 of FIG. 3, showing the apparatus 20 in greater detail. As mentioned above, the apparatus 20 includes a shuttle assembly 48 which allows for horizontal motion of the pad 26 and application surface 44. Advantageously, the shuttle assembly 48 allows for rapid movement of an electronic assembly after operation of the press 22 of FIG. 3. This aids in manufacturing speed, such that after a thermal interface has been formed for the electronic assembly, it is rapidly moved horizontally away from the press 22 for collection (e.g., by a robotic collection machine, or by a human being). Also, it allows for easy loading of a thermally-conductive polymer material onto the application surface 44 of the pad 26, and positioning of an electronic assembly above the application surface 44, on the spring-biased support pins 46. The shuttle assembly 48 slides along rails 58, and is slidably coupled to the rails 58 by way of coupling members 60 attached to the shuttle assembly 48. A piston 62 is attached at one end to the table 50 by way of a bracket 64, and is coupled at the opposite end to the shuttle assembly 48 by way of a shaft 63. The piston 62 could be electrically, pneumatically, or hydraulically powered.

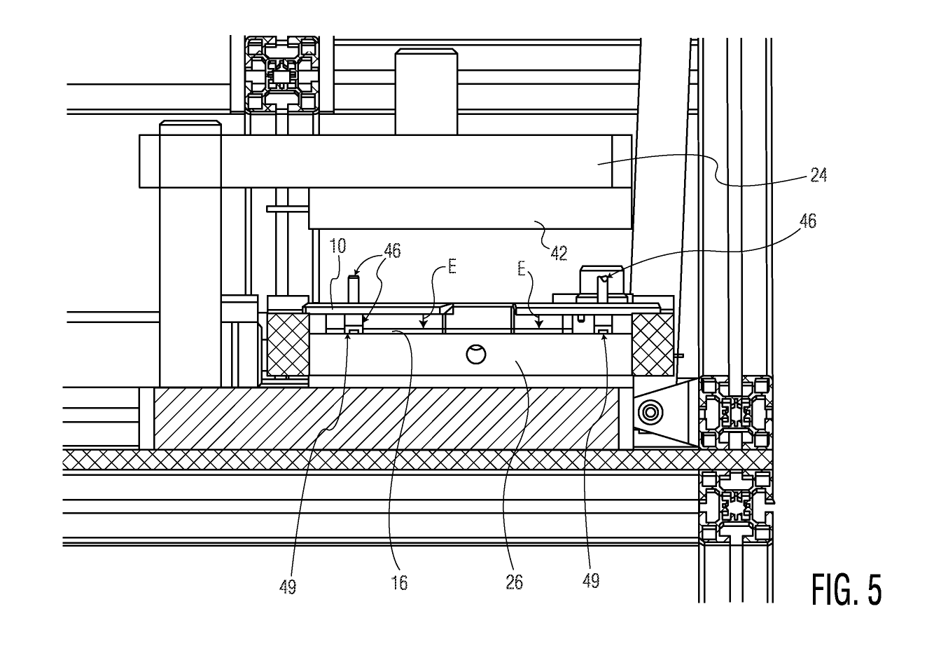

FIG. 5 is a side view showing operation of the apparatus 20 in greater detail. The electronic assembly 10 is supported on the spring-biased support pins 46 (which extend through apertures formed in the electronic assembly 10), above the thermally-conductive polymer 16 (which is positioned on the pad 26). Springs 49 bias the support pins 46, allowing the pins 46 to be compressed downwardly into the pad 26. When the die 24 is urged downward by the press 22 (not shown in FIG. 5), the grounding pad 42 contacts the electronic assembly 10 and forces same against the adhesive layer (not shown in FIG. 5) of the thermally conductive polymer 16, in the direction indicated by arrows E. Sufficient pressure is applied (as discussed above) to ensure that the thermally conductive polymer 16 bonds with the electronic assembly 10, and that no air gaps are formed between the thermally conductive polymer 16 and the electronic assembly 10. Thereafter, the die 24 and grounding pad 42 are moved upward, away from the electronic assembly 10. The springs 49 urge the support pins 46 upward, causing the electronic assembly 10 and the thermally conductive polymer 16 (now bonded to the electronic assembly 10) to move upward away from the pad 26. The shuttle assembly 48 (see FIG. 4) can then be actuated to move the bonded electronic assembly 10 and thermally conductive polymer 16 away from the die 42 and the grounding pad 42, for collection.

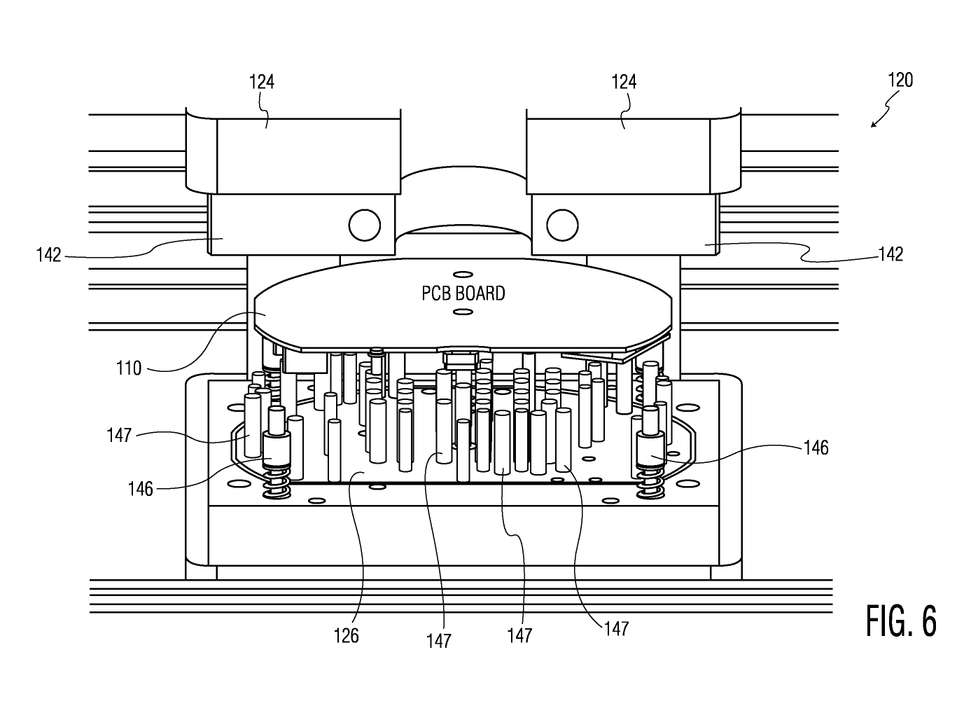

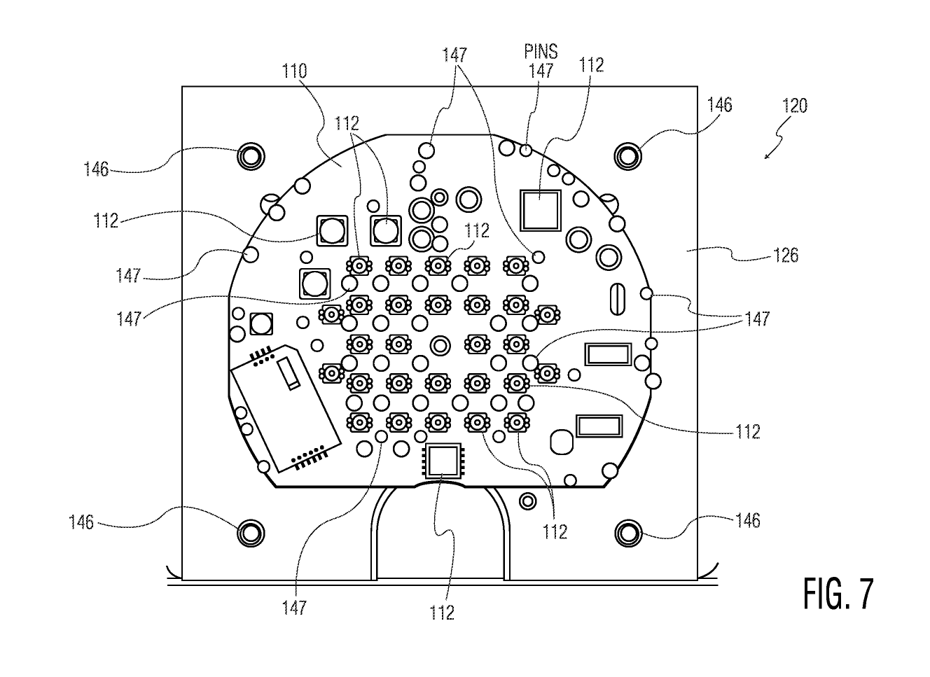

It is noted that the positions of the electronic assembly and the thermally conductive polymer could be reversed, if desired. That is, the electronic assembly could be supported by the pad of the present invention, and the thermally conductive polymer and adhesive layer could be pressed against a surface of the electronic assembly using the die of the present invention. Such a configuration is discussed below in connection with FIGS. 6-7.

FIG. 6 is a perspective view of another embodiment of the apparatus of the present invention, indicated generally at 120. In this embodiment, the electronic assembly (e.g., printed circuit board (PCB)) 110 is supported, face-down (i.e., electronic components of the assembly 110 are faced downwardly) by a plurality of upright pins 147 extending upwardly from the pad 126. The die 124 and grounding pad 142 exert pressure downwardly on a thermally conductive polymer and adhesive (not shown), which are positioned on the electronic assembly 110. Optionally, a substrate (not shown) could be positioned between the thermally conductive polymer and adhesive and the die 124 and grounding pad 142, if it is desired to bond the thermally conductive polymer to such a substrate. Such a substrate could include, but is not limited to, a wall forming part of a housing for the electronic assembly 110, such as a housing for an underwater LED pool light. Spring-biased support pins 146 support the substrate (if provided) or the thermally conductive polymer (if it extends beyond the perimeter of the electronic assembly 110), and are compressed when the die 124 and grounding pad 142 are urged downward by a press so as to apply pressure to the electronic assembly 110, the thermally conductive polymer and adhesive, and, optionally, the substrate. After curing of the adhesive, the die 124 and conductive pad 142 are lifted, and the support pins 146 are urged upward to move the bonded thermally conductive polymer and electronic assembly 110, as well as the substrate (if provided) away from the support pins 146. The completed, bonded components can then be removed from the support pins 146.

FIG. 7 is a diagrammatic view showing positioning of the support pins 147 relative to the electronic assembly 110. As can be seen, the pins 147 are positioned between electronic components 112 of the electronic assembly 110, so as to support the electronic assembly 110 without contacting the components 112. The spring-biased support pins 146 are offset from the electronic assembly 110, and could be compressed by a substrate (not shown) to which the electronic assembly is bonded when the die is operated. Optionally, the pins 146 could be compressed by a thermally conductive polymer to which the electronic assembly 110 is bonded, if the polymer extends beyond the perimeter of the electronic assembly 110 (e.g., where the polymer forms part of a housing for the electronic assembly 110, such as a polymer housing for an underwater LED pool light). A shuttle assembly, similar to the shuttle assembly 48 discussed above, could also be provided.

FIG. 8 is an electrical schematic diagram showing the controller 28 of FIG. 2 in greater detail. The controller 28 includes a programmable logic controller 200 which is programmed to control a plurality of actuators 202 connected thereto. The actuators 202 could include motors for moving a shuttle assembly (e.g., the shuttle assembly 48, discussed above), as well as motors for opening and closing a safety door which protects an operator from injury during operation of the press 22. Additionally, the actuators 202 could include relays or switches for selectively actuating the press 22. Status indicator lights 204 (e.g., red and green LEDs) are provided for indicating operational status of the press 22, and are controlled by the controller 200. Operation pushbutton switches 206 allow an operator to selectively operate the press 22 by pressing corresponding close/press and open/eject buttons. Service control switches 208 are provided for allowing service personnel to safely disarm selected portions of the apparatus of the present invention (e.g., the press 22, the shuttle assembly 48, or a safety door) to service same. A two-hand switch 210 is connected to the controller 200, and also allows for remote operation of the press 22. Limit switches 212 monitor operation of the apparatus of the present invention (e.g., position of the press 22, position of the shuttle assembly 48, and position of the safety door), and indicate to the controller 200 when operational limits have been reached (e.g., the safety door has reached a fully open or closed position, the press 22 has reached a desired position, or the shuttle assembly 48 has reached a desired position). A master power switch 214 allows a user to selectively control power to the controller 28, and an emergency stop switch 216 interrupts power to the controller 28 in the event of an emergency. A power supply 218 provides 24 volt direct current (DC) electrical power to the controller 28. It is noted that the controller 28 could be substituted with a specially-programmed, general purpose computer (e.g., a personal computer), an embedded computer system, or any other suitable controller/computing device without departing from the spirit or scope of the present invention.

FIGS. 9A-9B are diagrams showing event handling processes programmed into and executed by the programmable logic controller 200 of FIG. 8. The event handler processes 1-2 control operation of the safety door and press. Event handler processes 3-6 raise the press and slide out the shuttle assembly 48 when the two-finger switch 210 of FIG. 8 is actuated. Event handler processes 7-8 cause the shuttle assembly 48 to slide in, and the safety door to close, when the two finger switch 210 is operated. Event handler processes 9-10 cause the press 22 to be operated for a predetermined period of time (e.g., 20 seconds), and to apply a pre-determined pressure to the thermally conductive polymer, adhesive, and electronic assembly to ensure a bond between these components (e.g., 90 psi). The event handler processes 1-10 could be programmed using any suitable high- or low-level programming language (e.g., C, C++, assembler language, HDL, etc.).

Having thus described the invention in detail, it is to be understood that the foregoing description is not intended to limit the spirit or scope thereof. What is desired to be protected is set forth in the following claims.

What is claimed is:

1. A method for manufacturing a thermal interface for an electronic assembly, comprising the steps of:
providing a thermally conductive polymer having an adhesive layer formed thereon;
pressing a surface of the electronic assembly against the adhesive layer; and
allowing the adhesive layer to cure so that the thermally conductive polymer and the electronic assembly are in thermal communication with each other.

2. The method of claim 1, further comprising positioning the surface of the electronic assembly in facing relationship with the adhesive layer prior to pressing the surface against the adhesive layer.

3. The method of claim 2, further comprising positioning the thermally conductive polymer on a low durometer pad prior to pressing the surface of the electronic assembly against the adhesive layer.

4. The method of claim 1, wherein the step of pressing the surface of the electronic assembly against the adhesive layer comprises applying pressure to the electronic assembly using a die.

5. The method of claim 4, further comprising moving the die away from the electronic assembly after the adhesive layer cures.

6. The method of claim 1, wherein the step of allowing the adhesive layer to cure further comprises allowing the adhesive layer to cure so that no air gaps are formed between the thermally conductive polymer and the electronic assembly.

7. A method for manufacturing a thermal interface for an electronic assembly, comprising the steps of:
providing a thermally conductive polymer having an adhesive layer formed thereon;
pressing the adhesive layer and the thermally conductive polymer against a surface of the electronic assembly; and
allowing the adhesive layer to cure so that the thermally conductive polymer and the electronic assembly are in thermal communication with each other.

8. The method of claim 7, further comprising positioning the surface of the electronic assembly in facing relationship with the adhesive layer prior to pressing the surface against the adhesive layer.

9. The method of claim 8, further comprising positioning the electronic assembly on a plurality of upright support pins prior to pressing the adhesive layer and the thermally conductive polymer against the surface of the electronic assembly.

10. The method of claim 7, wherein the step of pressing the adhesive layer and the thermally conductive polymer against the surface of the electronic assembly against the adhesive layer comprises applying pressure to the thermally conductive polymer and the adhesive layer using a die.

11. The method of claim 10, further comprising moving the die away from the adhesive layer and the thermally conductive polymer after the adhesive layer cures.

12. The method of claim 7, wherein the step of allowing the adhesive layer to cure further comprises allowing the adhesive layer to cure so that no air gaps are formed between the thermally conductive polymer and the electronic assembly.

13. An apparatus for forming a thermal interface for an electronic assembly, comprising:
a pad for supporting a thermally conductive polymer, the thermally conductive polymer having an adhesive layer formed thereon;
a press for pressing a surface of an electronic assembly against the adhesive layer of the thermally conductive polymer; and
a controller for controlling operation of the press, the controller causing the press to maintain pressure against the electronic assembly and the thermally conductive polymer until the adhesive layer cures and the thermally conductive polymer is in thermal communication with the electronic assembly.

14. The apparatus of claim 13, wherein the pad comprises a low durometer pad.

15. The apparatus of claim 13, further comprising a shuttle assembly for supporting the pad and selectively moving the pad toward and away from the press.

16. The apparatus of claim 13, further comprising a die connected to the press.

17. The apparatus of claim 16, wherein the die contacts desired portions of the electronic assembly to press the surface of the electronic assembly against the thermally conductive polymer.

18. The apparatus of claim 13, wherein the die includes means for grounding the electronic assembly to prevent electrical charges from damaging the electronic assembly.

19. The apparatus of claim 13, further comprising means for supporting the electronic assembly above the thermally conductive polymer prior to pressing the surface of the electronic assembly against the adhesive layer.

20. The apparatus of claim 19, wherein said means for supporting the electronic assembly comprises a plurality of spring-biased support pins.

21. The apparatus of claim 20, wherein the plurality of spring-biased support pins are compressed when the electronic assembly is pressed against the adhesive layer.

22. The apparatus of claim 21, wherein the plurality of spring-biased support pins urge the electronic assembly and the thermally conductive polymer away from the pad after the adhesive layer cures.

23. An apparatus for forming a thermal interface for an electronic assembly, comprising:
a pad having a plurality of upright support pins for supporting an electronic assembly;
a press for pressing an adhesive layer and a thermally conductive polymer against a surface of the electronic assembly; and
a controller for controlling operation of the press, the controller causing the press to maintain pressure against the thermally conductive polymer and the adhesive layer until the adhesive layer cures and the thermally conductive polymer is in thermal communication with the electronic assembly.

24. The apparatus of claim 23, wherein the pad comprises a low durometer pad.

25. The apparatus of claim 23, further comprising a shuttle assembly for supporting the pad and selectively moving the pad toward and away from the press.

26. The apparatus of claim 23, further comprising a die connected to the press.

27. The apparatus of claim 26, wherein the die contacts desired portions of the thermally conductive polymer to press the thermally conductive polymer and the adhesive layer against the surface of the electronic assembly.

28. The apparatus of claim 23, wherein the die includes means for grounding the electronic assembly to prevent electrical charges from damaging the electronic assembly.

29. The apparatus of claim 23, farther comprising means for supporting the thermally conductive polymer above the electronic assembly polymer prior to pressing the thermally conductive polymer against the surface of the electronic assembly.

30. The apparatus of claim 29, wherein said means for supporting the thermally conductive polymer comprises a plurality of spring-biased support pins.

31. The apparatus of claim 30, wherein the plurality of spring-biased support pins are compressed when the thermally conductive polymer and the adhesive layer are pressed against the surface of the electronic assembly.

32. The apparatus of claim 31, wherein the plurality of spring-biased support pins urge the electronic assembly and the thermally conductive polymer away from the pad after the adhesive layer cures.

33. An electronic apparatus, comprising:
a printed circuit board having a plurality of electronic components mounted thereto; and
a thermally conductive polymer mounted to a surface of the printed circuit board for drawing heat through the printed circuit board and away from the plurality of electronic components.

34. The electronic apparatus of claim 33, further comprising a layer of adhesive between the printed circuit board and the thermally conductive polymer.

35. The electronic apparatus of claim 33, wherein the electronic apparatus comprises an underwater pool light and the plurality of electronic components comprises a plurality of light-emitting diodes.

36. The electronic apparatus of claim 35, wherein the thermally conductive polymer forms part of a housing for the underwater pool light.
